(19) United States
(12) Patent Application Publication
(10) Pub. No.: US 2019/0051611 A1
(43) Pub. Date: Feb. 14, 2019

(54) SEMICONDUCTOR PACKAGE BLOCKING ELECTROMAGNETIC INTERFERENCE AND ELECTRONIC SYSTEM HAVING THE SAME

(71) Applicant: SAMSUNG ELECTRONICS CO., LTD., Suwon-si (KR)

(72) Inventor: YEONG SEOK KIM, Hwaseong-si (KR)

(73) Assignee: SAMSUNG ELECTRONICS CO., LTD., Suwon-si (KR)

(21) Appl. No.: 15/867,045

(22) Filed: Jan. 10, 2018

(30) Foreign Application Priority Data
Aug. 11, 2017 (KR) 10-2017-0102542

(51) Int. Cl. H01L 23/552; H01L 25/18; H01L 23/31

(52) U.S. Cl. CPC H01L 23/552; H01L 23/3121; H01L 25/18

(57) ABSTRACT

A semiconductor package includes a substrate, semiconductor chips disposed on the substrate, and a ground pad disposed on or in the substrate and adjacent to any one or any combination of the semiconductor chips. The semiconductor package further includes an encapsulant disposed to seal an upper portion of the substrate, the semiconductor chips, and the ground pad, a trench disposed through the encapsulant to the ground pad, to isolate the semiconductor chips, and an electromagnetic interference (EMI) shielding film disposed to cover a surface of the encapsulant and the trench, the EMI shielding film including an adhesive resin, and the EMI shielding film being electrically connected to the ground pad.

### CROSS-REFERENCE TO THE RELATED APPLICATION

This application claims priority from Korean Patent Application No. 10-2017-0102542, filed on Aug. 11, 2017, the disclosure of which is incorporated herein by reference in its entirety.

### BACKGROUND

### 1. Field

Apparatuses and methods consistent with example embodiments relate to a semiconductor package including an electromagnetic wave shielding film and a method of manufacturing the same.

### 2. Description of Related Art

A System in Package (SiP) is one package including a plurality of semiconductor chips. The SiP can include a plurality of semiconductor chips (e.g., a processor, a memory, and a wireless transceiver) that perform various functions, and include passive elements, to operate as one system. The SiP can include a semiconductor chip (e.g., a wireless fidelity (WiFi) chip, a baseband chip, etc.) that causes an electromagnetic wave radiation. In this case, there is a use for a technique for shielding the electromagnetic interference (EMI) because the other semiconductor chips in the SiP can malfunction due to the influence of the electromagnetic wave.

Various techniques for shielding EMI have been introduced. For example, an EMI shielding film may be formed on a semiconductor chip that causes an electromagnetic wave radiation. However, a process of forming an EMI shielding film may be complex.

### SUMMARY

According to example embodiments, there is provided a semiconductor package including a substrate, semiconductor chips disposed on the substrate, and a ground pad disposed on or in the substrate and adjacent to any one or any combination of the semiconductor chips. The semiconductor package further includes an encapsulant disposed to seal an upper portion of the substrate, the semiconductor chips, and the ground pad, a trench disposed through the encapsulant to the ground pad, to isolate the semiconductor chips, and an electromagnetic interference (EMI) shielding film disposed to cover a surface of the encapsulant and the trench, the EMI shielding film including an adhesive resin, and the EMI shielding film being electrically connected to the ground pad.

According to example embodiments, there is provided a semiconductor package including a first semiconductor chip and a second semiconductor chip that are disposed on a substrate, a ground pad disposed adjacent to the first semiconductor chip or the second semiconductor chip, and an encapsulant disposed to cover the first semiconductor chip and the second semiconductor chip. The semiconductor package further includes a trench disposed through the encapsulant to the ground pad, and an electromagnetic interference (EMI) shielding film disposed to cover side walls of the trench, a bottom of the trench and a surface of the encapsulant, the EMI shielding film including thermoplastic polyurethane. The EMI shielding film includes a first portion disposed on the side walls and the bottom of the trench, and a second portion disposed on the first semiconductor chip and the second semiconductor chip. The second portion is continuous to the first portion.

According to example embodiments, there is provided a method of manufacturing a semiconductor package, the method including mounting semiconductor chips on a printed circuit board including a ground pad so that the ground pad is adjacent to any one or any combination of the semiconductor chips, forming an encapsulant to cover the semiconductor chips and the ground pad, forming a trench through the encapsulant to expose the ground pad, and forming an electromagnetic interference (EMI) shielding film to cover a surface of the encapsulant and the trench.

According to example embodiments, there is provided a semiconductor package including a substrate, semiconductor chips disposed on the substrate, and a ground pad disposed on the substrate and between the semiconductor chips. The semiconductor package further includes an encapsulant disposed to cover the substrate and the semiconductor chips, a first trench disposed through the encapsulant to the ground pad, and an electromagnetic interference (EMI) shielding film disposed to cover the encapsulant, the first trench, and the ground pad, the EMI shielding film having elasticity, conductivity, and magnetism.

### BRIEF DESCRIPTION OF THE DRAWINGS

FIG. 1 is a plan view illustrating a semiconductor package according to an example embodiment.

FIG. 2 is a longitudinal sectional view of the semiconductor package of FIG. 1 and taken along line I-I′ illustrated in FIG. 1.

FIG. 3 is a longitudinal sectional view of a semiconductor package according to an example embodiment and taken along line I-I′ illustrated in FIG. 1.

FIG. 4 is a partially enlarged view of the semiconductor package illustrated in FIG. 3

FIGS. 5, 6 and 7 are longitudinal sectional views of semiconductor packages according to example embodiments and taken along line I-I′ illustrated in FIG. 1.

FIG. 8 is a plan view illustrating a semiconductor package according to an example embodiment.

FIG. 9 is a longitudinal sectional view of the semiconductor package of FIG. 8 and taken along line I-I′ illustrated in FIG. 8.

FIG. 10 is a plan view illustrating a semiconductor package according to an example embodiment.

FIG. 11 is a flowchart schematically illustrating a method of manufacturing a semiconductor package, according to an example embodiment.

FIG. 12 is a schematic view illustrating a portion of an apparatus for performing a pressing and heating process, according to an example embodiment.

FIG. 13 is a block diagram illustrating an electronic system including a memory system, according to an example embodiment.

### DETAILED DESCRIPTION OF EXAMPLE EMBODIMENTS

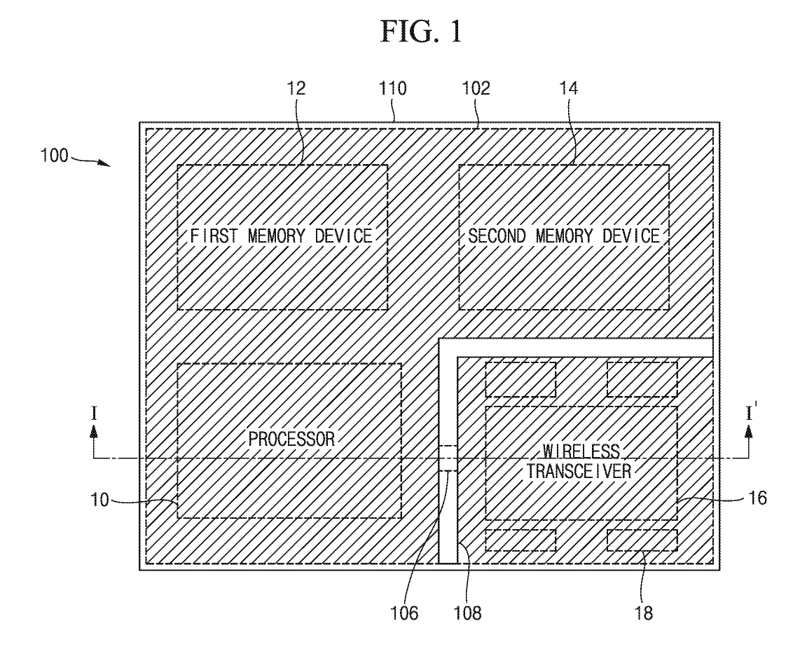

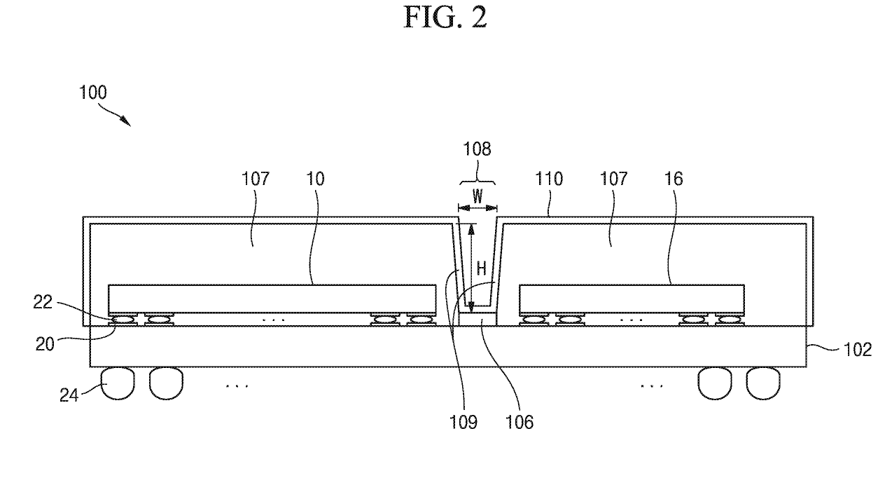

FIG. 1 is a plan view illustrating a semiconductor package 100 according to an example embodiment, and FIG. 2 is a longitudinal sectional view of the semiconductor package 100 of FIG. 1 and taken along line I-I′ illustrated in FIG. 1.

Referring to FIGS. 1 and 2, the semiconductor package 100 according to the example embodiment of the present inventive concept may be a system in package (SiP) including a printed circuit board (PCB) 102, and a processor 10, a first memory device 12, a second memory device 14, a wireless transceiver 16, and passive elements 18, which are mounted on the PCB 102. The semiconductor package 100 may include an encapsulant 107, a ground pad 106, a trench 108, and an EMI shielding film 110. Hereinafter, semiconductor chips 104 may refer to the processor 10, the first memory device 12, the second memory device 14, the wireless transceiver 16, another semiconductor chip, and the like, which are mounted on the PCB 102.

The PCB 102 may include a multi-layer structure in which multiple layers are stacked. The PCB 102 may include a signal line layer, a power line layer, and a ground line layer therein. The PCB 102 may include signal bonding pads, power bonding pads, and ground bonding pads 20, which are disposed thereon, and may include signal balls, power balls, and ground voltage balls 24, which are correspondingly connected to the signal bonding pads, the power bonding pads, and the ground bonding pads through the signal line layer, the power line layer, and the ground line layer. The processor 10, the first memory device 12, the second memory device 14, and the wireless transceiver 16 may be the semiconductor chips 104. Each of the semiconductor chips 104 may include signal pads, power pads, and ground voltage pads in a body thereof. The signal bonding pads, the power bonding pads, and the ground bonding pads of each of the semiconductor chips 104 may be disposed on the PCB 102 and correspondingly connected to the signal bonding pads, the power bonding pads, and the ground bonding pads 20 through bumps 22. The semiconductor chips 104 may be mounted on the PCB 102 by a wire bonding technique. Alternatively, the semiconductor chips 104 may be mounted on the PCB 102 by a flip chip technique using a solder. The semiconductor chips 104 may be mounted on the PCB 102 in a single layer structure and may also be vertically stacked and mounted on the PCB 102 in a structure of two or more layers. Alternatively, in the semiconductor package 100, a chip-scale package other than the semiconductor chips 104 may be mounted on the PCB 102.

The processor 10 may be a microprocessor or an application processor. Each of the first memory device 12 and the second memory device 14 may include a volatile memory device, such as a dynamic random access memory (DRAM) and a static random access memory (SRAM), or a non-volatile memory device, such as a NAND flash memory device, a NOR flash memory device, a magnetoresistive random access memory (MRAM), and a phase-change random access memory (PRAM). The wireless transceiver 16 may be a wireless fidelity (WiFi) chip, a radio frequency (RF) chip, or a baseband chip. The passive elements 18 may be resistors, inductors, and/or capacitors.

The ground pad 106 may be disposed on the PCB 102 to be adjacent to the wireless transceiver 16 to shield the wireless transceiver 16 that may cause an EMI. At least two ground pads 106 may be formed to be adjacent to the wireless transceiver 16. A shape of the ground pad 106 in FIG. 1 is an example, and the ground pad 106 may have a rectangular shape or a circular shape. The ground pad 106 may be electrically connected to the ground bonding pads 20 disposed on the PCB 102 that are correspondingly connected to the ground voltage pads disposed in the body of the wireless transceiver 16.

The encapsulant 107 may be formed to cover the PCB 102, the processor 10, the first memory device 12, the second memory device 14, the wireless transceiver 16, and the passive elements 18. The encapsulant 107 may be formed of an epoxy molding compound (EMC). The encapsulant 107 may protect the PCB 102 and the semiconductor chips 104 from an external environment. The encapsulant 107 may be cut by a cutting process to expose the ground pad 106 and to form the trench 108 that surrounds the wireless transceiver 16.

The trench 108 may be formed by a cutting process after forming the encapsulant 107 to cover the entirety of the semiconductor chips 104. The cutting process may be, for example, laser cutting and may be performed once. The trench 108 may cut the encapsulant 107 to expose at least one ground pad 106 and may be formed to isolate any one or any combination of the semiconductor chips 104. The trench 108 made by one cutting process substantially has no step and each of side surfaces 109 of the trench may form at least an 80 degree angle with a horizontal plane. The trench 108 may have a width W of 100 μm to 400 μm and a depth H of 500 μm to 1,000 μm. Alternatively, the trench 108 may have a width W of 100 μm to 300 μm and a depth H of 500 μm to 1,000 μm. A shape of the trench 108 is not limited to a shape illustrated in FIG. 2. The trench 108 may have a U shape and may have another shape.

The EMI shielding film 110 may be formed to cover upper portions of the encapsulant 107 and the ground pad 106. The EMI shielding film 110 may have conductivity and may be electrically connected to the ground pad 106. At least one ground pad 106 electrically connected to the EMI shielding film 110 may be provided. The EMI shielding film 110 that covers the side surfaces 109 of the trench may form at least an 80 degree angle with a horizontal plane. The EMI shielding film 110 may be formed by one pressing and heating process, for example, by a laminating process.

The EMI shielding film 110 may include a binder resin that keeps the form of a film and may include a thermosetting material, an elastic material, a material having conductivity, and/or a material having magnetism. The EMI shielding film 110 may include an acryl resin or a resin mainly composed of a modified product of the acryl resin as the binder resin. The EMI shielding film 110 may include ethylene oxide as the thermosetting material. The EMI shielding film 110 may include thermoplastic polyurethane (TPU) as the material having elasticity, and may further include butadiene, a nitrile, chloroprene, or isoprene as a material for reinforcing elasticity. The EMI shielding film 110 may include a resin obtained by mixing ethylene oxide and TPU.

The EMI shielding film 110 may include a metal powder including copper (Cu), silver (Ag), or the like as the material having conductivity. The EMI shielding film 110 may be electrically connected to the ground pad 106 by the metal powder and grounded. The EMI shielding film 110 may include a ferromagnetic material, such as nickel (Ni), iron (Fe), or an alloy powder obtained by mixing thereof, as the material having magnetism.

The EMI shielding film 110 may shield not only the electromagnetic wave from the outside of the package but also the electromagnetic wave caused by the chips inside the package. For example, the EMI shielding film 110 may shield an EMI having a frequency of several hundreds of MHz to several GHz. A thickness of a portion of the EMI shielding film 110 that covers the side surface 109 of the trench may be, for example, about 20 μm. A portion of the EMI shielding film 110 that covers a surface of the encapsulant 107 and a lower portion of the trench 108 may be formed thicker than the portion of the EMI shielding film 110 that covers the side surfaces 109 of the trench. The thickness of the EMI shielding film 110 may be changed according to a conductive material and a magnetic material, which are included therein.

The EMI shielding film 110 that covers the side surfaces 109 and the bottom portion of the trench and the EMI shielding film 110 that covers the surface of the encapsulant 107 may be one continuous film. The EMI shielding film 110 that covers the side surfaces 109 and the bottom portion of the trench may include the same material as the EMI shielding film 110 that covers the surface of the encapsulant 107. For example, the EMI shielding film 110 formed in the semiconductor package 100 may be formed of one material such as TPU and may include a conductive material and a magnetic material.

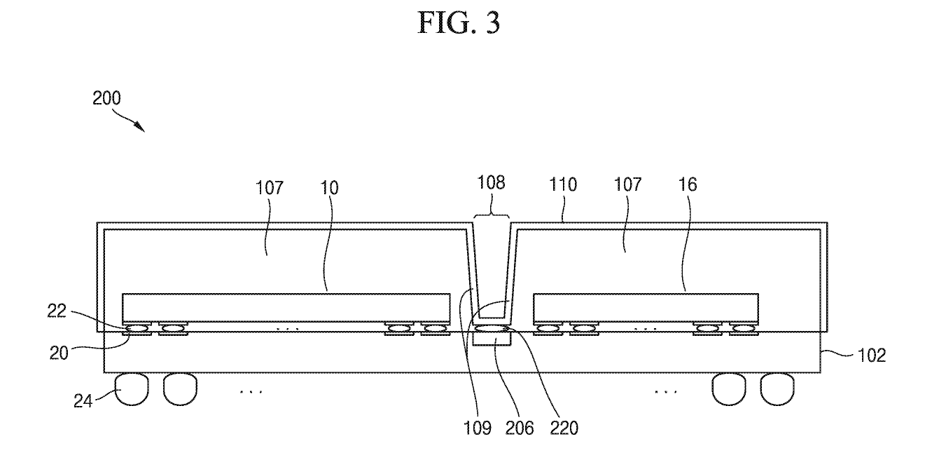

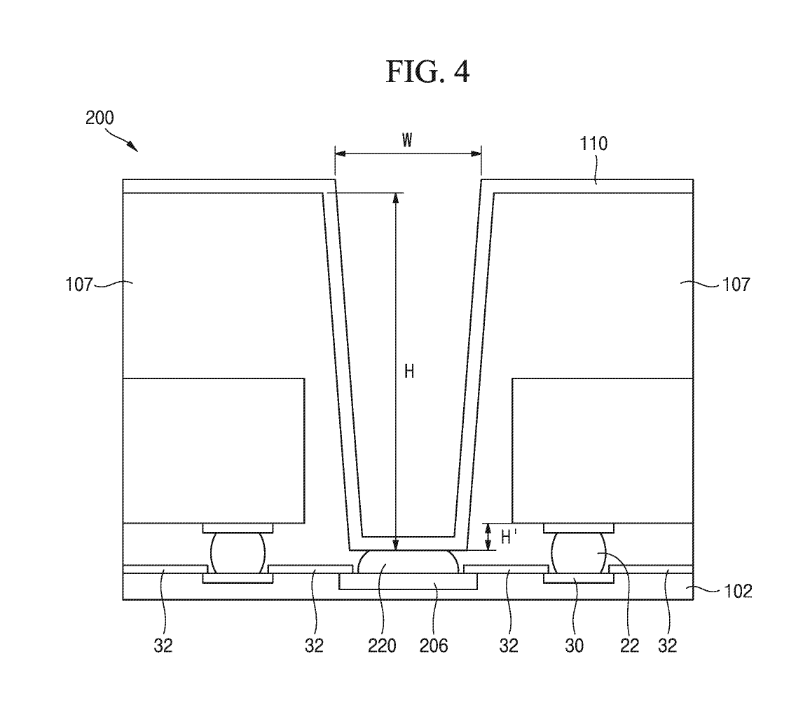

FIG. 3 is a longitudinal sectional view of a semiconductor package 200 according to an example embodiment and taken along line I-I′ illustrated in FIG. 1., and FIG. 4 is a partially enlarged view of the semiconductor package 200 illustrated in FIG. 3, namely, of the trench 108 between the processor 10 and the wireless transceiver 16.

Referring to FIGS. 3 and 4, it is illustrated that the semiconductor package 200 according to the example embodiment of the present inventive concept includes ground bonding pads 30 in a surface of the PCB 102. Further, a ground pad 206 may be formed in the surface of the PCB 102. The semiconductor package 200 may further include a solder on pad (SOP) 220 on the ground pad 206. The EMI shielding film 110 may be electrically connected to the ground pad 206 through the SOP 220. The SOP 220 may include a conductive material. When one or more ground pads 206 are formed in the semiconductor package 200, one or more SOPs 220 may be formed on each of the ground pads 206. In the other example embodiments of the present inventive concept, the SOP 220 may be formed on the ground pad 106.

Referring to FIG. 4, a case in which the ground pad 206 is electrically connected to the EMI shielding film 110 through the SOP 220 is enlarged and illustrated. In the example embodiment in which the ground pad 206 is included in the surface of the PCB 102, the SOP 220 may not be formed on the ground pad 206. The EMI shielding film 110 may bypass the SOP 220 and may be electrically connected to the ground pad 206. The ground pad 206 and the ground bonding pads 30 may be included in the surface of the PCB 102. The ground pad 206 may be electrically connected to the ground bonding pads 30. A solder mask 32 may be formed on the surface of the PCB 102 to cover portions of the ground pad 206 and the ground bonding pads 30.

A lower end of the trench 108 that abuts the SOP 220 may be formed at a lower level than lower ends of the semiconductor chips adjacent thereto. For example, in FIG. 4, the semiconductor chips are illustrated as being mounted on the PCB 102 by flip chip bonding. In this case, the lower end of the trench 108 may be formed to be as much as a height H′ lower than lower ends of the processor 10 and the wireless transceiver 16.

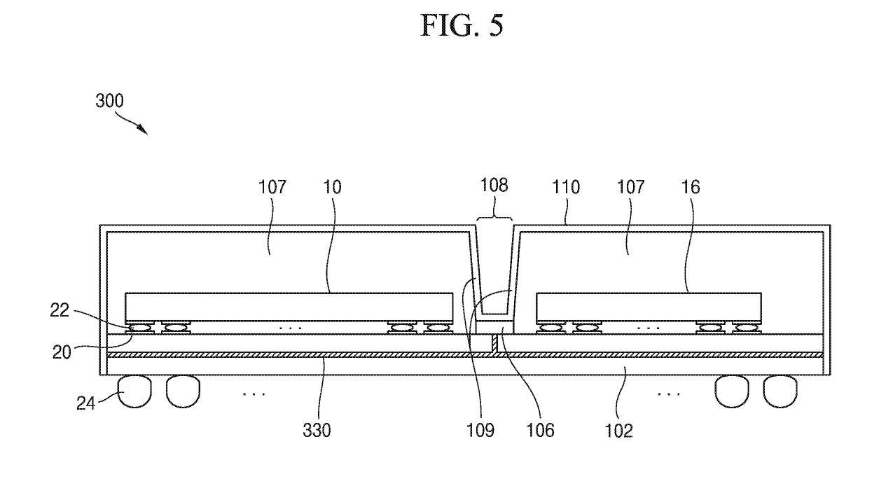

FIG. 5 is a longitudinal sectional view of a semiconductor package 300 according to an example embodiment.

Referring to FIG. 5, in the semiconductor package 300 according to the example embodiment of the present inventive concept, a ground layer 330 is illustrated as being formed in the PCB 102. The ground layer 330 may be electrically connected to the ground pad 106 formed on the PCB 102. In the other example embodiments of the present inventive concept, the ground layer 330 formed in the PCB 102 may be electrically connected to the ground pad 106.

In FIG. 5, the EMI shielding film 110 is illustrated as covering not only side surfaces of the encapsulant 107 but also side surfaces of the PCB 102. The ground layer 330 may be electrically connected to the EMI shielding film 110 on the side surfaces of the PCB 102. The ground layer 330 may be electrically connected to the EMI shielding film 110 on all of four side surfaces of the PCB 102 or may be electrically connected to the EMI shielding film 110 on some of the side surfaces of the PCB 102.

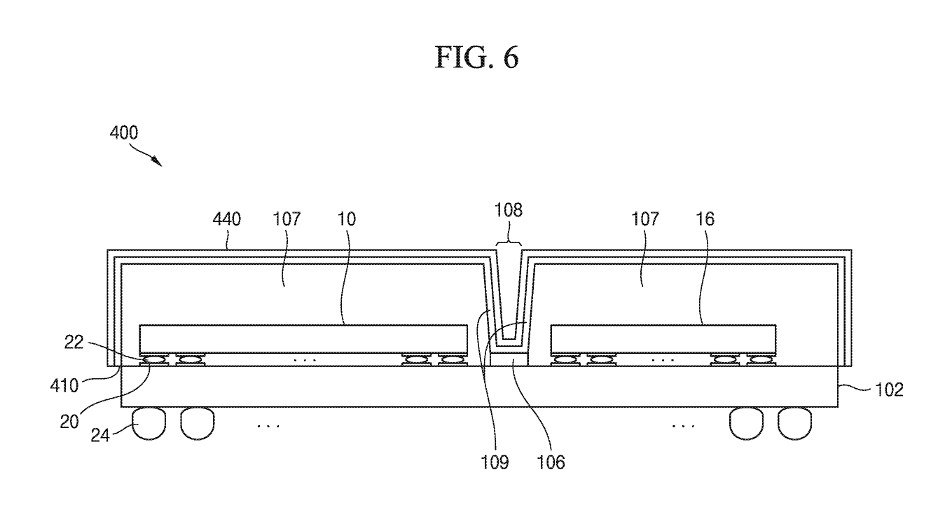

FIG. 6 is a longitudinal sectional view of a semiconductor package 400 according to an example embodiment.

Referring to FIG. 6, an additional layer 440 may be further formed on an EMI shielding film 410 according to the example embodiment of the present inventive concept.

The additional layer 440 may be formed as a metal deposited film to reinforce a function of blocking electromagnetic interference (EMI). The metal deposited film may be formed of aluminum (Al), copper (Cu), or indium (In).

The additional layer 440 formed on the EMI shielding film 410 that covers the side surfaces 109 of a trench may form at least an 80 degree angle with a horizontal plane. The additional layer 440 may be formed along with the EMI shielding film 410 by one pressing and heating process. The additional layer 440 may include TPU for elasticity.

The additional layer 440 may include iron (Fe) oxide, copper (Cu) oxide, and chromium (Cr) oxide used as dyes to perform a color expression function. The additional layer 440 may include carbon black. The additional layer 440 may adjust a color of the semiconductor package 400, using a dye, and thus enhance an appearance of the semiconductor package 400 and impart an aesthetic sense to a user.

One additional layer 440 may have a function of blocking EMI, and, at the same time, may have a color expression function. Alternatively, additional layers 440 having separate functions may be formed in a structure of two or more layers.

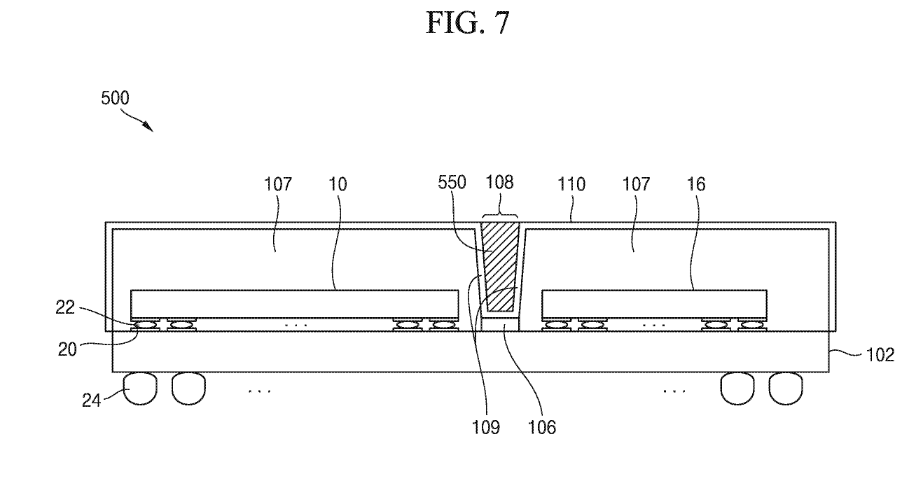

FIG. 7 is a longitudinal sectional view of a semiconductor package 500 according to an example embodiment.

Referring to FIG. 7, the semiconductor package 500 may include a partition 550 in the trench 108. The partition 550 may be formed on the EMI shielding film 110 formed on the trench 108. At least one partition 550 may be installed along the trench 108 and may be formed between semiconductor chips 104. The partition 550 may be a piece, and may be formed along a portion of the trench 108 or across an entire portion of the trench 108. The EMI shielding film 110 may be formed to surround side surfaces and a lower end of the partition 550. The partition 550 may include a conductive material and may reinforce a function of blocking EMI of the EMI shielding film 110.

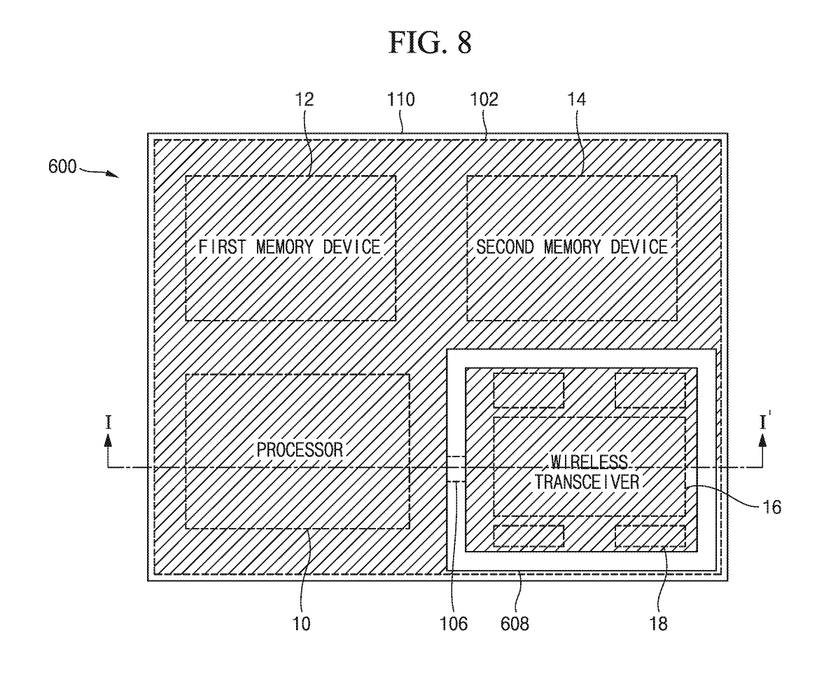

FIG. 8 is a plan view of a semiconductor package 600 according to an example embodiment.

Referring to FIG. 8, a trench 608 may be formed to be located outside the PCB 102 and to surround the semiconductor chip 104 that causes an EMI. The trench 608 may be formed, for example, to block the wireless transceiver 16, and any shape as long as it is for blocking the semiconductor chip 104 can be used without being limited to a shape thereof illustrated in FIG. 8.

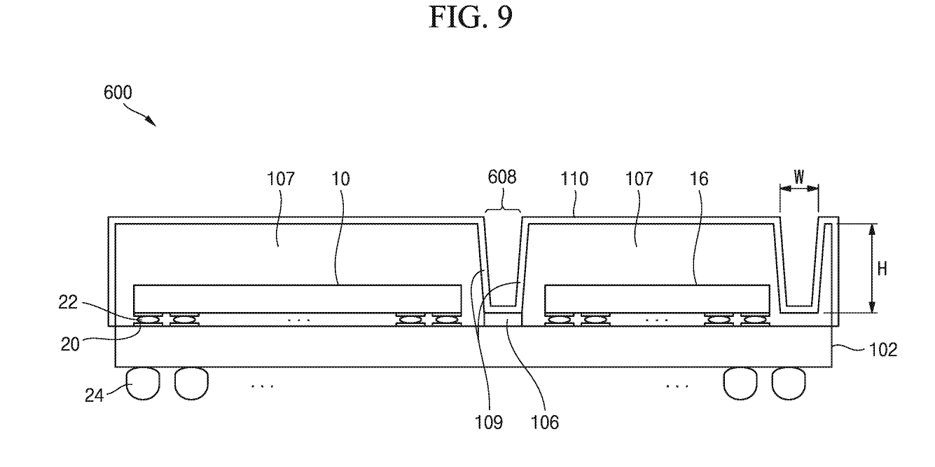

FIG. 9 is a longitudinal sectional view of the semiconductor package 600 of FIG. 8 and taken along line I-I′ illustrated in FIG. 8.

Referring to FIG. 9, as illustrated in the longitudinal sectional view, the trench 608 may be formed at both sides of the wireless transceiver 16 to surround the wireless transceiver 16. Although one ground pad 106 is illustrated in the longitudinal sectional view of FIG. 9, two or more ground pads 106 may be formed along the trench 608. The trench 608 may be more deeply formed to approach the PCB 102 at a portion in which the ground pad 106 is not formed, than at a portion in which the ground pad 106 is formed.

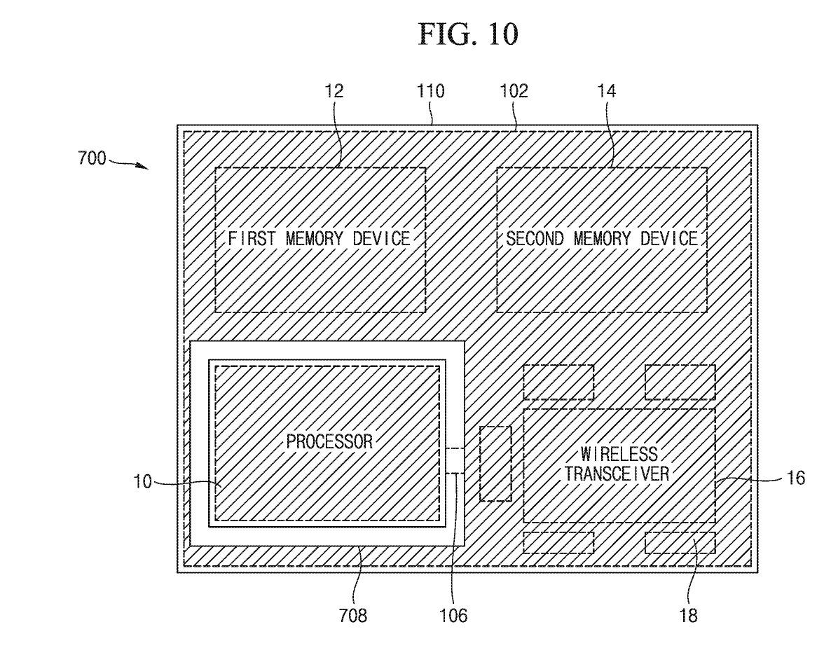

FIG. 10 is a plan view of a semiconductor package 700 according to an example embodiment.

Referring to FIG. 10, a trench 708 may be formed not only to surround a chip that causes an EMI but also to surround the semiconductor chip 104 to be protected from EMI.

For example, the ground pad 106 and the trench 708 are formed around an application processor (AP) chip (i.e., the processor 10) and covered with the EMI shielding film 110, and thus the AP chip may be protected from external EMI.

Next, a method of manufacturing a semiconductor package according to an example embodiment of the present inventive concept will be described.

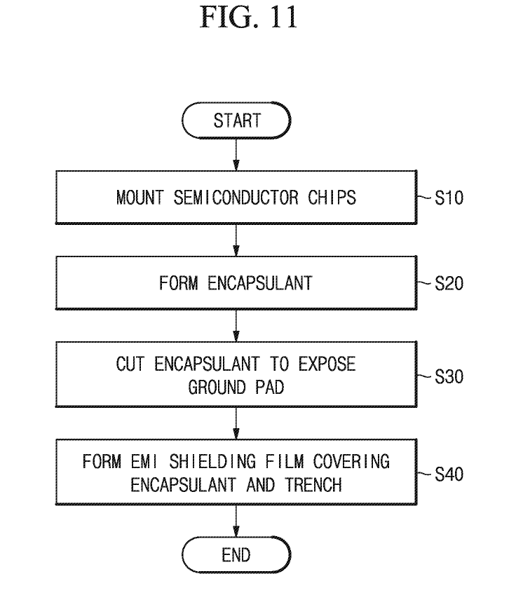

FIG. 11 is a flowchart schematically illustrating a method of manufacturing the semiconductor package 100, according to an example embodiment.

First, a PCB including at least one ground pad formed to be adjacent to at least one semiconductor chip of semiconductor chips to be disposed thereon is provided, and the semiconductor chips are mounted on the PCB (S10). The ground pad mounted on the PCB may be electrically connected to the semiconductor chips, or may be electrically connected to a ground layer formed in the PCB.

An encapsulant that covers the semiconductor chips and the ground pad that are mounted on the PCB is formed (S20). The encapsulant is cut by one cutting process to expose the at least one ground pad (S30). A groove may be formed by the cutting process, for example, by etching with a laser.

An EMI shielding film covering a surface of the encapsulant and an upper portion of a trench is formed by one pressing and heating process (S40). The pressing and heating process may be a laminating process.

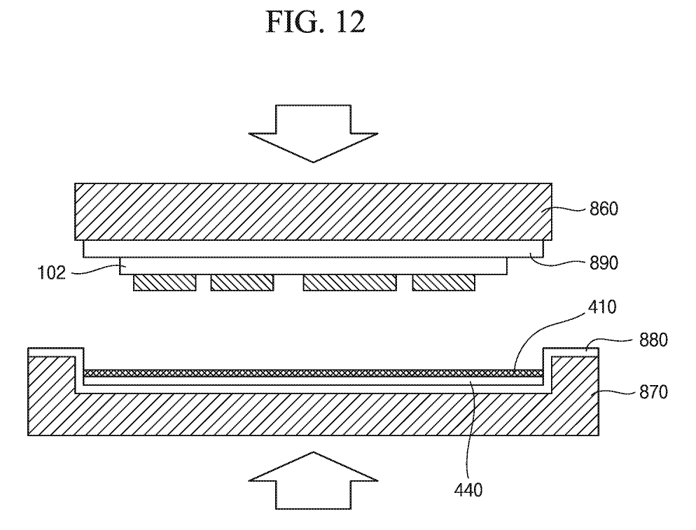

FIG. 12 is a schematic view illustrating a portion of an apparatus for performing a pressing and heating process, according to an example embodiment.

Referring to FIG. 12, the semiconductor package 100 according to the example embodiment of the present inventive concept is attached to a support 890. The support 890 is installed on an upper unit 860 so that an upper portion of the PCB 102 is turned downward. A cushion film 880 is formed on a lower unit 870, and an EMI shielding film 410 is formed on the cushion film 880 to come into contact with the semiconductor chips 104 mounted on the PCB 102. The semiconductor package 100 may further include an additional layer 440, and the additional layer 440 may be formed between the cushion film 880 and the EMI shielding film 410. The cushion film 880 may include a material such as polyethylene (PE), polypropylene (PP), polyvinyl chloride (PVC), polymethylpentene (PMP), polytetrafluoroethylene (PTFE), and the like.

In the pressing and heating process, the upper unit 860 and the lower unit 870 are engaged to come into contact with each other while the EMI shielding film 410 and the cushion film 880 are placed on the lower unit 870. A pattern matching the trench 108 may be formed on the lower unit 870 so that a film may be inserted into the trench 108 of the semiconductor package 100. The pressing and heating process may be performed at a temperature of 100 to 200° C. and a pressure of 10 to 100 MPa. The temperature and pressure of the pressing and heating process may be changed according to heights of the semiconductor chips 104.

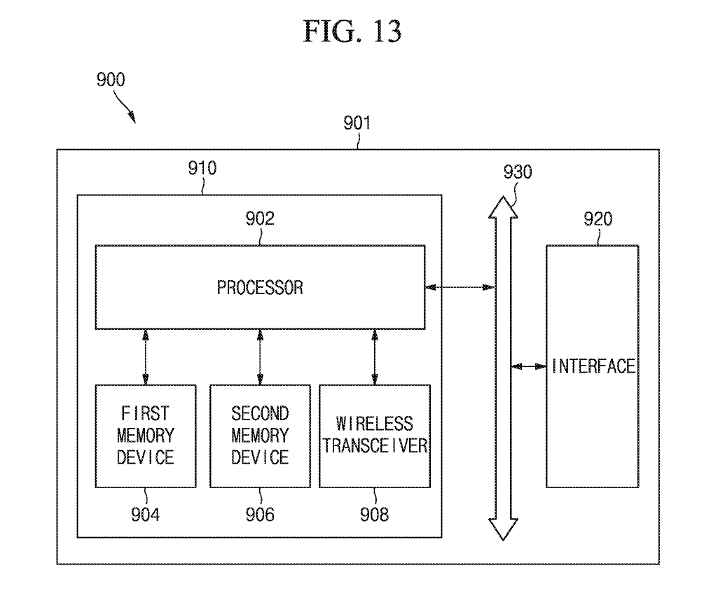

FIG. 13 is a block diagram illustrating an electronic system 900 including a memory system, according to an example embodiment.

Referring to FIG. 13, the electronic system 900 may include a body 901. The body 901 may be a system board or a mother board having a PCB and the like. The electronic system 900 may include a SiP 910 including a processor 902, a first memory device 904, a second memory device 906, and a wireless transceiver 908. The electronic system 900 may further include an interface 920 and a bus 930.

The processor 902 may control the electronic system 900. The processor 902 may control the first memory device 904 or the second memory device 906 to input and output data into and from the first memory device 904 or the second memory device 906, and may input and output data into and from the interface 920 through the bus 930. Further, the processor 902 may receive data received through the wireless transceiver 908 and output data to the wireless transceiver 908. The wireless transceiver 908 may transmit and receive data in a wireless manner. The electronic system 900 may be applied to an electronic device such as a mobile device.

The SiP 910 illustrated in FIG. 13 may have the same structure as the semiconductor packages as described above in FIGS. 1 to 9, and may be manufactured by the method of manufacturing a semiconductor package described in FIGS. 11 and 12. The electronic system 900 to which the example embodiment of the present inventive concept is applied can block interference of the EMI, and thus can improve the integrity of a data signal and the safety of a system operation.

According to the example embodiments of the present inventive concept, a process is simplified by performing one cutting process and one pressing and heating process after molding a printed circuit board, and thus an EMI shielding film for blocking electromagnetic interference (EMI) can be formed.

According to the example embodiments of the present inventive concept, a liquid material is excluded in a cutting process and a process of forming an EMI shielding film, and thus secondary contamination due to a liquid material non-product can be prevented and the reduction of a yield can be prevented.

According to the example embodiments of the present inventive concept, an additional layer can be formed on an EMI shielding film that is provided as a film for shielding an EMI. The additional layer can reinforce a function of adjusting the color of a surface of a semiconductor package or a function of blocking EMI.

As is traditional in the field of the inventive concepts, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the inventive concepts. Further, the blocks, units and/or modules of the example embodiments may be physically combined into more complex blocks, units and/or modules without departing from the scope of the inventive concepts.

While the example embodiments of the present inventive concept have been described with reference to the accompanying drawings, it may be understood by those skilled in the art that various modifications may be made without departing from the scope of the present inventive concept and without changing features. Therefore, the above-described example embodiments may be considered in a descriptive sense only and not for purposes of limitation.

1. A semiconductor package comprising:
a substrate;
semiconductor chips disposed on the substrate;
a ground pad disposed on or in the substrate and adjacent to any one or any combination of the semiconductor chips;
an encapsulant disposed to seal an upper portion of the substrate, the semiconductor chips, and the ground pad;
a trench disposed through the encapsulant to the ground pad, to isolate the semiconductor chips; and
an electromagnetic interference (EMI) shielding film disposed to cover a surface of the encapsulant and the trench, the EMI shielding film comprising an adhesive resin, and the EMI shielding film being electrically connected to the ground pad.

2. The semiconductor package of claim 1, wherein the EMI shielding film has elasticity, conductivity, and magnetism.

3. The semiconductor package of claim 2, wherein the EMI shielding film comprises a conductive metal powder, and
wherein the conductive metal powder comprises copper or silver.

4. The semiconductor package of claim 2, wherein the EMI shielding film comprises nickel, iron, or an alloy of the nickel and the iron.

5. The semiconductor package of claim 2, wherein the EMI shielding film comprises thermoplastic polyurethane.

6. The semiconductor package of claim 5, wherein the EMI shielding film further comprises butadiene, a nitrile, chloroprene, or isoprene.

7. The semiconductor package of claim 2, further comprising an additional layer disposed on the EMI shielding film.

8. The semiconductor package of claim 7, wherein the additional layer comprises iron oxide, copper oxide, chromium oxide, or carbon black.

9. The semiconductor package of claim 7, wherein the additional layer is a metal-deposited film, and
wherein the metal-deposited film comprises copper, indium, or aluminum.

10. The semiconductor package of claim 1, wherein the trench comprises no step,
wherein each of side walls of the trench forms at least an 80 degree angle with a horizontal plane,
wherein a width of the trench ranges from 100 to 300 μm, and
wherein a depth of the trench ranges from 500 to 1,000 μm.

11. The semiconductor package of claim 1, wherein at least one of the semiconductor chips causes an EMI or is affected by the EMI.

12. The semiconductor package of claim 1, further comprising a solder on pad (SOP) disposed on the ground pad,
wherein the EMI shielding film is electrically connected to the ground pad through the SOP.

13. A semiconductor package comprising:
a first semiconductor chip and a second semiconductor chip that are disposed on a substrate;
a ground pad disposed adjacent to the first semiconductor chip or the second semiconductor chip;
an encapsulant disposed to cover the first semiconductor chip and the second semiconductor chip;
a trench disposed through the encapsulant to the ground pad; and
an electromagnetic interference (EMI) shielding film disposed to cover side walls of the trench, a bottom of the trench and a surface of the encapsulant, the EMI shielding film comprising thermoplastic polyurethane, and
wherein the EMI shielding film comprises:
a first portion disposed on the side walls and the bottom of the trench; and
a second portion disposed on the first semiconductor chip and the second semiconductor chip, and
wherein the second portion is continuous to the first portion.

14. The semiconductor package of claim 13, further comprising a solder on pad (SOP) disposed on the ground pad,
wherein the EMI shielding film is electrically connected to the ground pad through the SOP.

15. The semiconductor package of claim 13, wherein a lower end of the first portion of the EMI shielding film is disposed at a level lower than lower ends of the first semiconductor chip and the second semiconductor chip.

16. The semiconductor package of claim 13, wherein the trench comprises a U shape.

17. The semiconductor package of claim 13, further comprising a partition disposed in the trench, the partition being electrically connected to the ground pad through the EMI shielding film,
wherein the EMI shielding film surrounds side surfaces and a bottom surface of the partition.

18-22. (canceled)

23. A semiconductor package comprising:
a substrate;
semiconductor chips disposed on the substrate;
a ground pad disposed on the substrate and between the semiconductor chips;
an encapsulant disposed to cover the substrate and the semiconductor chips;
a first trench disposed through the encapsulant to the ground pad; and
an electromagnetic interference (EMI) shielding film disposed to cover the encapsulant, the first trench, and the ground pad, the EMI shielding film having elasticity, conductivity, and magnetism.

24. The semiconductor package of claim 23, further comprising a ground layer disposed in the substrate and connected to the ground pad,
wherein the EMI shielding film is further disposed to cover first side surfaces of the encapsulant and second side surfaces of the substrate, and
wherein the ground layer is further connected to the second side surfaces of the EMI shielding film.

25. The semiconductor package of claim 23, further comprising a second trench disposed through the encapsulant and adjacent to a first side surface of one of the semiconductor chips,
wherein the first trench is disposed adjacent to a second side surface of the one of the semiconductor chips.
